(19) United States
(12) Patent Application Publication
(10) Pub. No.: US 2026/0338932 A1
(43) Pub. Date: Oct. 29, 2026

(54) TRANSMIT/RECEIVE CHANNEL, TRAP CIRCUIT AND UNDERWATER DETECTION DEVICE

(71) Applicant: FURUNO ELECTRIC CO., LTD., Nishinomiya-City (JP)

(72) Inventors: Futoshi KONDO, Kobe (JP); Junpei NAGAUCHI, Amagasaki (JP)

(73) Assignee: FURUNO ELECTRIC CO., LTD., Nishinomiya-City (JP)

(21) Appl. No.: 19/533,591

(22) Filed: Feb. 9, 2026

(30) Foreign Application Priority Data
Apr. 25, 2025 (GB) 2506174.8

(51) Int. Cl. G01S 7/524; G01S 7/526; H03H 7/01

(52) U.S. Cl. CPC G01S 7/524; G01S 7/526; H03H 7/0161; H03H 7/175; H03H 7/1775

(57) ABSTRACT

A transmit/receive channel including an ultrasonic transducer, a transmitter, a receiver, a voltage booster circuit, and a switch circuit is disclosed. The voltage booster circuit is configured to amplify a voltage of a transmission signal generated by the transmitter and output the amplified transmission signal to the ultrasonic transducer during transmission, and to filter a reception signal generated by the ultrasonic transducer and output the filtered reception signal to the receiver during reception. The switch circuit is configured to electrically couple the transmitter and the voltage booster circuit during the transmission, and to electrically couple the receiver and the voltage booster circuit during the reception.

### CROSS-REFERENCE TO RELATED APPLICATION(S)

The application claims priority under 35 U.S.C. § 119 to United Kingdom Patent Application No. 2506174.8, which was filed on Apr. 25, 2025, the entire disclosure of which is hereby incorporated by reference.

### TECHNICAL FIELD

The present disclosure relates to a transmit/receive channel, a trap circuit, an underwater detection device, and a transmit/receive method.

### BACKGROUND

LC resonance trap circuit and diode switch trap circuit are conventional trap circuits for underwater detection devices for supplying a transmission signal to a transducer and a reception signal to a preamplifier.

### SUMMARY

A first aspect of the present disclosure relates to a transmit/receive channel including an ultrasonic transducer, a transmitter, a receiver, a voltage booster circuit, and a switch circuit. The voltage booster circuit is configured to amplify a voltage of a transmission signal generated by the transmitter and output the amplified transmission signal to the ultrasonic transducer during transmission, and to filter a reception signal generated by the ultrasonic transducer and output the filtered reception signal to the receiver during reception. The switch circuit is configured to electrically couple the transmitter and the voltage booster circuit during the transmission, and to electrically couple the receiver and the voltage booster circuit during the reception. This makes it possible to achieve both a wide bandwidth and a reduced number of components.

In an embodiment, the transmit/receive channel may further include a filtering circuit configured to further filter the filtered reception signal filtered by the voltage booster circuit and output it to the receiver. The voltage booster circuit in combination with the filtering circuit may constitute a bandpass filter. The filtering circuit may include an inductor and a capacitor.

A second aspect of the present disclosure relates to a trap circuit connected to an ultrasonic transducer, a transmitter and a receiver. The trap circuit includes a voltage booster circuit and a switch circuit. The voltage booster circuit is configured to amplify a voltage of a transmission signal generated by the transmitter and output the amplified transmission signal to the ultrasonic transducer during transmission, and to filter a reception signal generated by the ultrasonic transducer and output the filtered reception signal to the receiver during reception. The switch circuit is configured to electrically couple the transmitter and the voltage booster circuit during the transmission, and to electrically couple the receiver and the voltage booster circuit during the reception. This makes it possible to achieve both a wide bandwidth and a reduced number of components.

A third aspect of the present disclosure relates to an underwater detection device that includes the transmit/reception channel according to the first aspect. This makes it possible to apply a transmit/receive channel that achieves both a wide bandwidth and a reduced number of components.

A fourth aspect of the present disclosure relates to a transmit/receive method of a transmit/receive channel including an ultrasonic transducer, a transmitter, a receiver, a voltage booster circuit, and a switch circuit. The method includes electrically coupling, by the switch circuit, the transmitter and the voltage booster circuit during transmission; amplifying, by the voltage booster circuit, a voltage of a transmission signal generated by the transmitter and outputting the amplified transmission signal to the ultrasonic transducer during the transmission; electrically coupling, by the switch circuit, the receiver and the voltage booster circuit during reception; and filtering a reception signal generated by the ultrasonic transducer and outputting the filtered reception signal to the receiver during the reception. This makes it possible to achieve both a wide bandwidth and a reduced number of components.

### BRIEF DESCRIPTION OF THE DRAWINGS

FIG. 1 is a diagram showing an example of a sonar.

FIG. 2 is a diagram showing an example of a transmit/receive channel according to a first embodiment.

FIG. 3A is a diagram showing an example of a transmission operation.

FIG. 3B is a diagram showing an example of a reception operation.

FIG. 4 is a diagram showing a voltage booster circuit and a filtering circuit.

FIG. 5 is a diagram showing a modification of the first embodiment.

FIG. 6 is a diagram showing an example of a transmit/receive channel according to a second embodiment.

FIG. 7A is a diagram showing an example of an operation during transmission.

FIG. 7B is a diagram showing an example of an operation during reception.

### DETAILED DESCRIPTION

Embodiments of the present disclosure will be described below with reference to the drawings. In the present specification and drawings, an element like a previously described element with respect to a previous drawing may be denoted by the same reference numeral and a detailed description may be omitted accordingly.

A problem of the conventional LC resonance type trap circuit is that it has a narrow bandwidth, and a problem of the conventional diode switch type trap circuit is that it has a large number of components.

In view of the above problems, it is an object of the present disclosure to provide a transmit/receive channel, a trap circuit, an underwater detection device, and a transmit/receive method that can achieve both a wide bandwidth and a reduced number of components.

### Underwater Detection Device

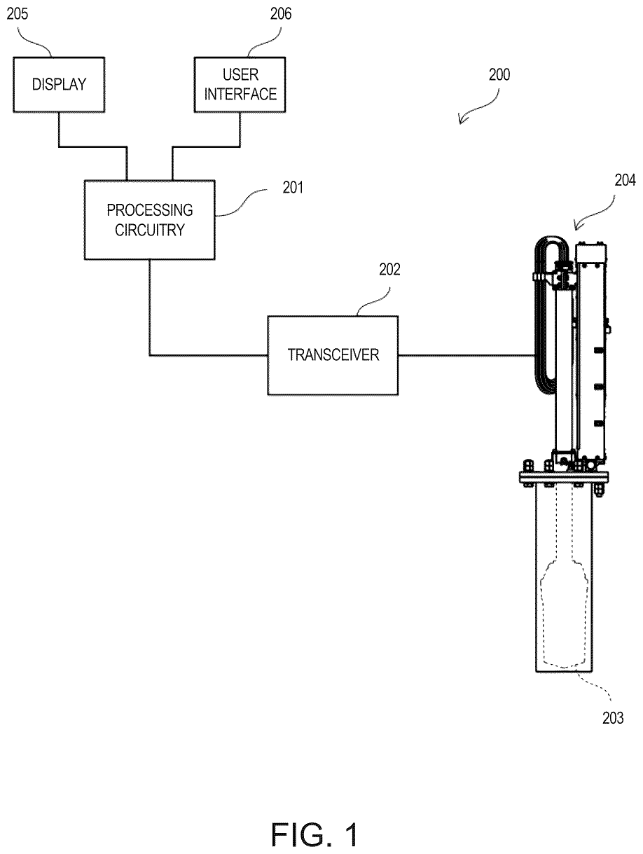

FIG. 1 is a diagram showing a configuration example of a sonar 200, which is an example of underwater detection device. The sonar 200 includes processing circuitry 201, a transceiver 202, a transducer 203, an up-and-down device 204, a display 205, and a user interface 206.

The processing circuitry 201 may be a computer including a CPU, a RAM, a ROM, a nonvolatile memory, an input/output interface, and the like.

The transceiver 202 includes transmission circuitry and reception circuitry. The transmission circuitry generates a transmission signal and outputs it to the transducer 203. The reception circuitry amplifies and A/D converts an echo signal from the transducer 203 and outputs it to the processing circuitry 201.

The transducer 203 includes an ultrasonic transducer that emits ultrasonic waves in water based on the transmission signal from the transceiver 202 and outputs the echo signal based on a reflected wave to the transceiver 202.

The up-and-down device 204 moves the transducer 203 up and down. The up-and-down device 204 projects the transducer 203 downward from the bottom of a ship on which the sonar 200 is installed when the sonar 200 is in use, and stores the transducer 203 above the bottom of the ship when the sonar 200 is not in use.

The display 205 is, for example, a liquid crystal display or an organic EL display, and displays a sonar image generated by the processing circuitry 201. The user interface 206 is, for example, a pointing device such as a track ball or a touch panel.

The sonar 200 may be a scanning sonar for detecting an object in the water by simultaneously emitting ultrasonic waves from the transducer 203 in a part of or all directions.

The transceiver 202 includes a trap circuit according to some embodiments. The transceiver 202 and the transducer 203 constitute a transmit/receive channel according to the embodiments and realize the transmit/receive method according to the embodiments.

### First Embodiment

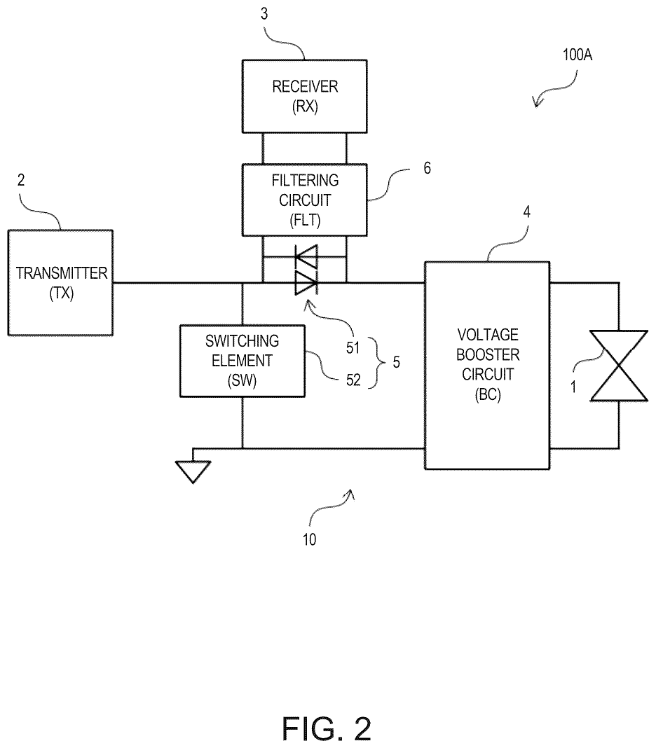

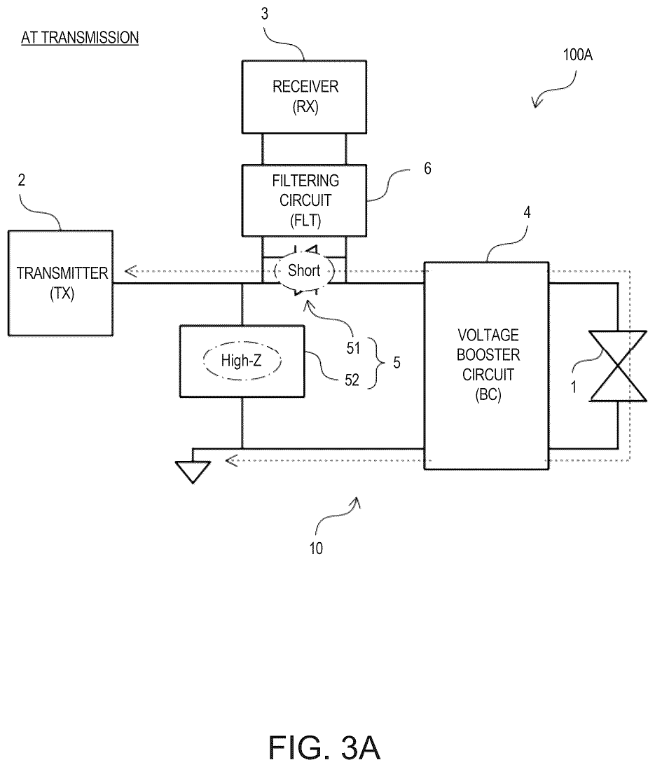

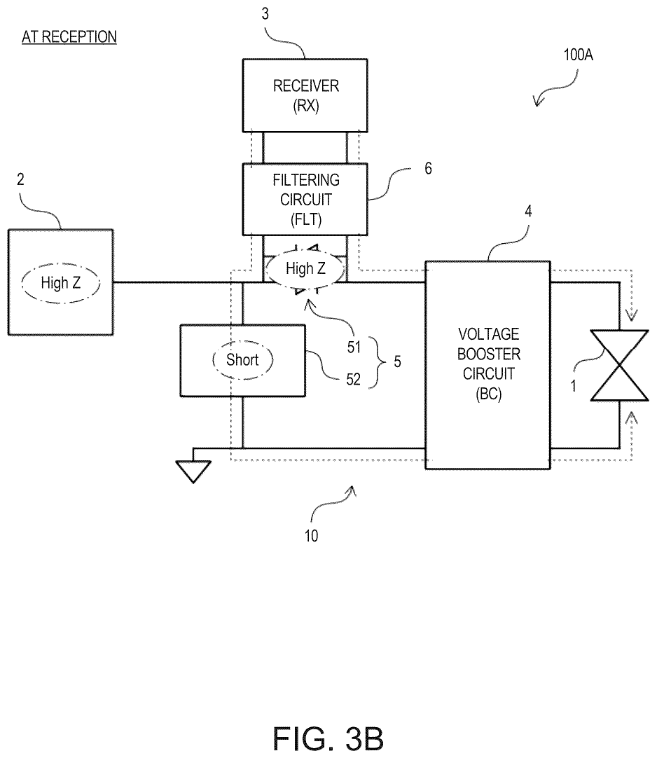

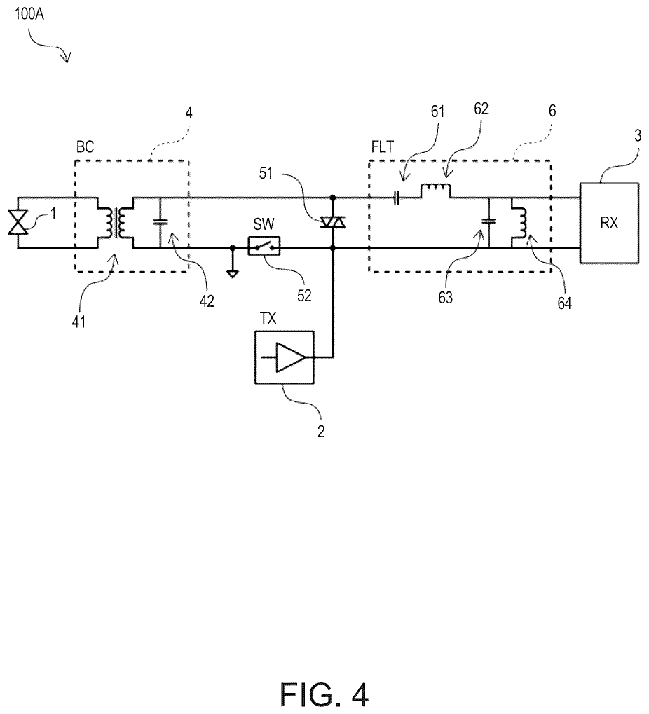

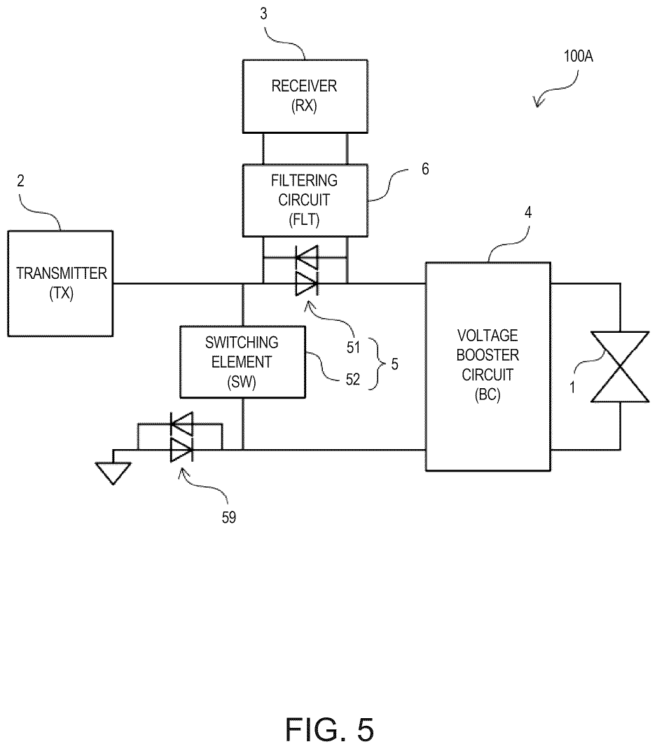

FIG. 2 is a diagram showing an example configuration of a transmit/receive channel 100A according to a first embodiment. FIG. 3A is a diagram showing an example of an operation during transmission, and FIG. 3B is a diagram showing an example of an operation during reception. FIG. 4 is a diagram showing specific examples of a voltage booster circuit 4 and a filtering circuit 6. FIG. 5 is a diagram showing a modification of the first embodiment.

The transmit/receive channel 100A includes an ultrasonic transducer 1, a transmitter 2, a receiver 3, a voltage booster circuit 4, a switch circuit 5, and a filtering circuit 6. Among them, the voltage booster circuit 4 and the switch circuit 5 constitute a trap circuit 10 connected to the ultrasonic transducer 1, the transmitter 2, and the receiver 3. The trap circuit 10 may further include the filtering circuit 6.

The ultrasonic transducer 1 is a transducer that mutually converts electric signals and ultrasonic vibrations. The transmitter 2 is a circuit that generates a transmission signal during transmission. The receiver 3 is a circuit that acquires a reception signal during reception.

The voltage booster circuit 4 is arranged between the transmitter 2 and the ultrasonic transducer 1. The receiver 3 is connected to a line branched from a line between the transmitter 2 and the voltage booster circuit 4. The voltage booster circuit 4 may include, for example, a transformer 41 and a capacitor 42 (see FIG. 4). In another example, the voltage booster circuit 4 may include an inductor L and a capacitor C. The voltage booster circuit 4 may also be called a transmission matching circuit.

The switch circuit 5 may include a varistor 51 and a switching element 52. The varistor 51 may be connected in series with the transmitter 2, between the transmitter 2 and the voltage booster circuit 4. The varistor 51 may be connected in parallel with the receiver 3. In other words, the receiver 3 may be connected to both ends of the varistor 51.

The switching element 52 may be any suitable switching device, including mechanical switches (such as relays) and semiconductor switches (such as MOSFETs, BJTs, IGBTs, or analog switch ICs). The switching element 52 may be connected in parallel with the transmitter 2 and in series with the receiver 3. Specifically, one end of the switching element 52 is connected between the transmitter 2 and the varistor 51. The other end of the switching element 52 may be connected to ground, or to a varistor 59 placed before the ground to allow floating during reception, as shown in FIG. 5.

The filtering circuit 6 may be arranged between the receiver 3 and the varistor 51. That is, the filtering circuit 6 may be connected in parallel with the receiver 3 and also in parallel with the varistor 51. The filtering circuit 6 may include, for example, capacitors 61 and 63 and inductors 62 and 64 (see FIG. 4).

As shown in FIG. 3A, at transmission time, a voltage higher than a threshold voltage is applied by the transmission signal from the transmitter 2, which short-circuits the varistor 51. As a result, the transmitter 2 and the voltage booster circuit 4 are electrically coupled. In this state, the switching element 52 is in a high impedance state. When the transmitter 2 and the voltage booster circuit 4 are electrically coupled, the voltage booster circuit 4 amplifies a voltage of the transmission signal generated by the transmitter 2, and outputs the amplified transmission signal to the ultrasonic transducer 1.

As shown in FIG. 3B, at reception time, the switching element 52 is short-circuited, and the receiver 3 and the voltage booster circuit 4 are electrically coupled. In this state, the varistor 51 and the transmitter 2 are in a high impedance state. When the receiver 3 and the voltage booster circuit 4 are electrically coupled, the voltage booster circuit 4 filters a reception signal generated by the ultrasonic transducer 1, and the filtering circuit 6 may further filter the reception signal filtered by the voltage booster circuit 4 and output it to the receiver 3.

In this embodiment, the voltage booster circuit 4 performs both amplifying of the transmission signal and filtering of the reception signal. That is, the voltage booster circuit 4 is also used to filter the reception signal. Thus, the number of components for filtering can be reduced, and the overall underwater detection device can be miniaturized.

Moreover, the use of the switching element 52 makes it possible to achieve a wide bandwidth. Furthermore, by arranging the switching element 52 in front of the voltage booster circuit 4 so that a voltage before amplification is applied to the switching element 52, a required withstand voltage is reduced, making it possible to achieve a smaller size for the switching element 52 itself.

Specific configurations of the voltage booster circuit 4 and the filtering circuit 6 are described with reference to FIG. 4. In this embodiment, a combination of the voltage booster circuit 4 and the filtering circuit 6 may constitute a bandpass filter. The bandpass filter can be designed with any transfer function such as a Butterworth filter.

In the example of FIG. 4, the filtering circuit 6 includes a capacitor 61 and an inductor 62 connected in series with the receiver 3. The filtering circuit 6 may further include a capacitor 63 and an inductor 64 connected in parallel with the receiver 3.

Constants of the voltage booster circuit 4, such as for example transmission voltage and input power, are designed based on requirements for transmission.

Constants of the filtering circuit 6 are designed so that the combination of the voltage booster circuit 4 and the filtering circuit 6 as a whole achieves desired filter characteristics, such as center frequency and passband of the bandpass filter. That is, since the constants of the voltage booster circuit 4 are designed as described above, the constants of the remaining capacitors 61 and 63 and inductors 62 and 64 are assigned so as to achieve the desired filter characteristics.

The constants of the filtering circuit 6 may be designed in consideration of LC components of the ultrasonic transducer 1 in addition to the constants of the voltage booster circuit 4.

Note that the filtering circuit 6 may be omitted if desired filter characteristics can be obtained only with the voltage booster circuit 4.

### Second Embodiment

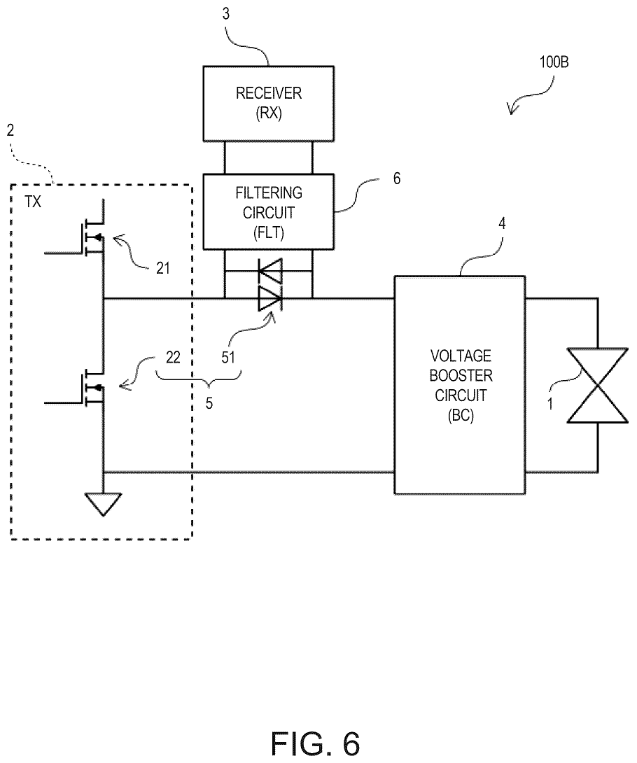

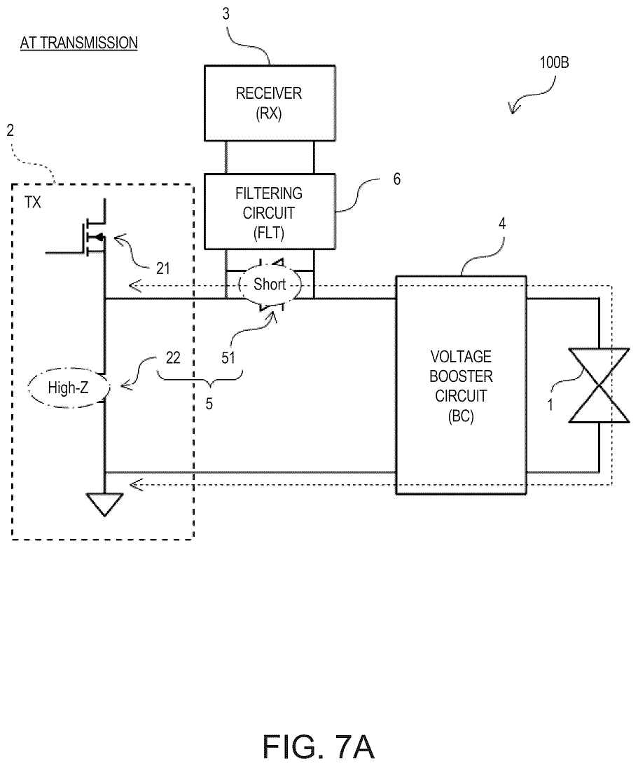

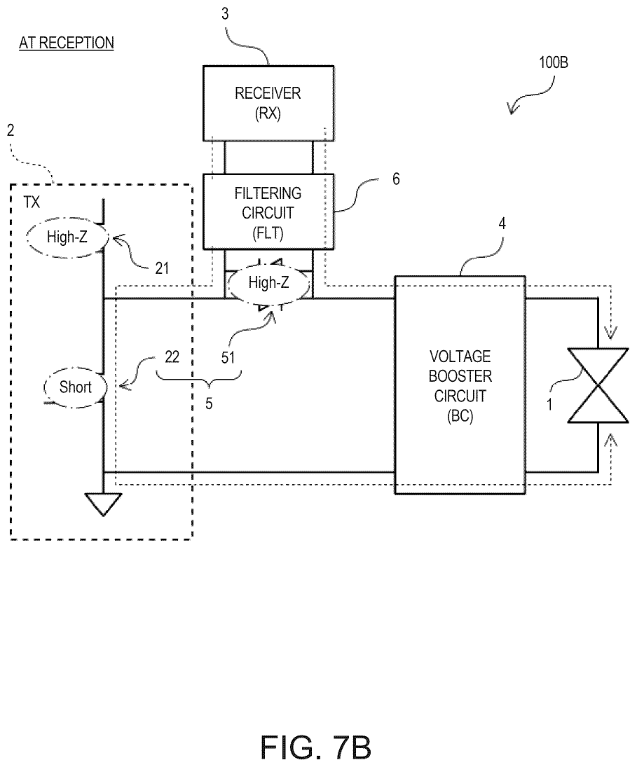

FIG. 6 is a diagram showing an example configuration of a transmit/receive channel 100B according to a second embodiment. FIG. 7A is a diagram showing an example of an operation during transmission, and FIG. 7B is a diagram showing an example of an operation during reception. Elements which overlap with those of the above-described embodiments may be denoted by the same reference numerals, and detailed description thereof may be omitted.

The transmitter 2 may include a high-side switching amplifier 21 and a low-side switching amplifier 22. The switching amplifiers 21 and 22 may generate a transmission pulse by alternately switching on and off during transmission. The switching amplifiers 21 and 22 are, for example, FET.

In the second embodiment, the low-side switching amplifier 22 is used as a switching element of the switch circuit 5, thereby further reducing the number of components compared with the first embodiment.

As shown in FIG. 7A, at transmission time, the low-side switching amplifier 22 is in a high impedance state and when a voltage higher than the threshold voltage is applied to the varistor 51 by the transmission pulse from the transmitter 2, the varistor 51 is short-circuited and the transmitter 2 and the voltage booster circuit 4 are electrically coupled. When the transmitter 2 and the voltage booster circuit 4 are electrically coupled, the voltage booster circuit 4 amplifies the voltage of the transmission signal generated by the transmitter 2 and outputs the amplified transmission signal to the ultrasonic transducer 1.

As shown in FIG. 7B, at reception time, the low-side switching amplifier 22 is short-circuited and the receiver 3 and the voltage booster circuit 4 are electrically coupled. In this state, the varistor 51 and the high-side switching amplifier 21 are in a high-impedance state. When the receiver 3 and the voltage booster circuit 4 are electrically coupled, the voltage booster circuit 4 filters the reception signal generated by the ultrasonic transducer 1, and the filtering circuit 6 may further filter the reception signal filtered by the voltage booster circuit 4 and output it to the receiver 3.

In the second embodiment, varistor 59 may be provided before the ground to allow floating of one end of the switching amplifier 22 at reception time, as in the modification of FIG. 5.

Although embodiments of the present disclosure have been described above, the present disclosure is not limited to the embodiments described above, and it is of course possible for a person skilled in the art to make various changes.

As explained above and reiterated below, the present disclosure includes, without limitation, the following example implementations.

Clause 1. A transmit/receive channel comprising an ultrasonic transducer; a transmitter; a receiver; a voltage booster circuit configured to amplify a voltage of a transmission signal generated by the transmitter and output the amplified transmission signal to the ultrasonic transducer during transmission, and to filter a reception signal generated by the ultrasonic transducer and output the filtered reception signal to the receiver during reception; and a switch circuit configured to electrically couple the transmitter and the voltage booster circuit during the transmission, and to electrically couple the receiver and the voltage booster circuit during the reception.

Clause 2. The transmit/receive channel of clause 1 further comprising a filtering circuit configured to further filter the filtered reception signal filtered by the voltage booster circuit and output it to the receiver.

Clause 3. The transmit/receive channel of clause 2, wherein the voltage booster circuit in combination with the filtering circuit constitutes a bandpass filter.

Clause 4. The transmit/receive channel of clause 2 or clause 3, wherein the filtering circuit comprises an inductor and a capacitor.

Clause 5. The transmit/receive channel of any of the preceding clauses, wherein the switch circuit comprises a varistor connected in series with the transmitter and in parallel with the receiver.

Clause 6. The transmit/receive channel of any of the preceding clauses, wherein the switch circuit comprises a switching element connected in parallel with the transmitter and in series with the receiver.

Clause 7. The transmit/receive channel of any one of clauses 1 to 5, wherein the transmitter comprises a switching amplifier and the switching amplifier is also used as a switching element in the switch circuit.

Clause 8. A trap circuit connected to an ultrasonic transducer, a transmitter and a receiver, comprising a voltage booster circuit configured to amplify a voltage of a transmission signal generated by the transmitter and output the amplified transmission signal to the ultrasonic transducer during transmission, and to filter a reception signal generated by the ultrasonic transducer and output the filtered reception signal to the receiver during reception; and a switch circuit configured to electrically couple the transmitter and the voltage booster circuit during the transmission, and to electrically couple the receiver and the voltage booster circuit during the reception.

Clause 9. An underwater detection device comprising the transmit/receive channel of any of clauses 1 to 7.

Clause 10. A transmit/receive method of a transmit/receive channel comprising an ultrasonic transducer, a transmitter, a receiver, a voltage booster circuit and a switch circuit, the method comprising electrically coupling, by the switch circuit, the transmitter and the voltage booster circuit during transmission; amplifying, by the voltage booster circuit, a voltage of a transmission signal generated by the transmitter and outputting the amplified transmission signal to the ultrasonic transducer during the transmission; electrically coupling, by the switch circuit, the receiver and the voltage booster circuit during reception; and filtering a reception signal generated by the ultrasonic transducer and outputting the filtered reception signal to the receiver during the reception.

### Terminology

Although the embodiments of the present disclosure have been described above, the present disclosure is not limited to the embodiments described above, and various modifications can be made by those skilled in the art.

It is to be understood that not necessarily all objects or advantages may be achieved in accordance with any particular embodiment described herein. Thus, for example, those skilled in the art will recognize that certain embodiments may be configured to operate in a manner that achieves or optimizes one advantage or group of advantages as taught herein without necessarily achieving other objects or advantages as may be taught or suggested herein.

All of the processes described herein may be embodied in, and fully automated via, software code modules executed by a computing system that includes one or more computers or processors. The code modules may be stored in any type of non-transitory computer-readable medium or other computer storage device. Some or all the methods may be embodied in specialized computer hardware.

Many other variations than those described herein will be apparent from this disclosure. For example, depending on the embodiment, certain acts, events, or functions of any of the algorithms described herein can be performed in a different sequence, can be added, merged, or left out altogether (e.g., not all described acts or events are necessary for the practice of the algorithms). Moreover, in certain embodiments, acts or events can be performed concurrently, e.g., through multi-threaded processing, interrupt processing, or multiple processors or processor cores or on other parallel architectures, rather than sequentially. In addition, different tasks or processes can be performed by different machines and/or computing systems that can function together.

The various illustrative logical blocks and modules described in connection with the embodiments disclosed herein can be implemented or performed by a machine, such as a processor. A processor can be a microprocessor, but in the alternative, the processor can be a controller, microcontroller, or state machine, combinations of the same, or the like. A processor can include electrical circuitry configured to process computer-executable instructions. In another embodiment, a processor includes an application specific integrated circuit (ASIC), a field programmable gate array (FPGA) or other programmable device that performs logic operations without processing computer-executable instructions. A processor can also be implemented as a combination of computing devices, e.g., a combination of a digital signal processor (DSP) and a microprocessor, a plurality of microprocessors, one or more microprocessors in conjunction with a DSP core, or any other such configuration. Although described herein primarily with respect to digital technology, a processor may also include primarily analog components. For example, some or all of the signal processing algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

Conditional language such as, among others, “can,” “could,” “might” or “may,” unless specifically stated otherwise, are otherwise understood within the context as used in general to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

Any process descriptions, elements or blocks in the flow diagrams described herein and/or depicted in the attached figures should be understood as potentially representing modules, segments, or portions of code which include one or more executable instructions for implementing specific logical functions or elements in the process. Alternate implementations are included within the scope of the embodiments described herein in which elements or functions may be deleted, executed out of order from that shown, or discussed, including substantially concurrently or in reverse order, depending on the functionality involved as would be understood by those skilled in the art.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations. For example, “a processor configured to carry out recitations A, B and C” can include a first processor configured to carry out recitation A working in conjunction with a second processor configured to carry out recitations B and C. The same holds true for the use of definite articles used to introduce embodiment recitations. In addition, even if a specific number of an introduced embodiment recitation is explicitly recited, those skilled in the art will recognize that such recitation should typically be interpreted to mean at least the recited number (e.g., the bare recitation of “two recitations,” without other modifiers, typically means at least two recitations, or two or more recitations).

It will be understood by those within the art that, in general, terms used herein, are generally intended as “open” terms (e.g., the term “including” should be interpreted as “including but not limited to,” the term “having” should be interpreted as “having at least,” the term “includes” should be interpreted as “includes but is not limited to,” etc.).

For expository purposes, the term “horizontal” as used herein is defined as a plane parallel to the plane or surface of the floor of the area in which the system being described is used or the method being described is performed, regardless of its orientation. The term “floor” can be interchanged with the term “ground” or “water surface.” The term “vertical” refers to a direction perpendicular to the horizontal as just defined. Terms such as “above,” “below,” “bottom,” “top,” “side,” “higher,” “lower,” “upper,” “over,” and “under,” are defined with respect to the horizontal plane.

As used herein, the terms “attached,” “connected,” “mated” and other such relational terms should be construed, unless otherwise noted, to include removable, moveable, fixed, adjustable, and/or releasable connections or attachments. The connections/attachments can include direct connections and/or connections having intermediate structure between the two components discussed.

Numbers preceded by a term such as “approximately,” “about,” and “substantially” as used herein include the recited numbers, and also represent an amount close to the stated amount that still performs a desired function or achieves a desired result. For example, the terms “approximately,” “about,” and “substantially” may refer to an amount that is within less than 10% of the stated amount. Features of embodiments disclosed herein preceded by a term such as “approximately,” “about,” and “substantially” as used herein represent the feature with some variability that still performs a desired function or achieves a desired result for that feature.

It should be emphasized that many variations and modifications may be made to the above-described embodiments, the elements of which are to be understood as being among other acceptable examples. All such modifications and variations are intended to be included herein within the scope of this disclosure and protected by the following claims.

What is claimed is:

1. A transmit/receive channel comprising:
an ultrasonic transducer;
a transmitter;
a receiver;
a voltage booster circuit configured:
to amplify a voltage of a transmission signal generated by the transmitter and output the amplified transmission signal to the ultrasonic transducer during transmission, and
to filter a reception signal generated by the ultrasonic transducer and output the filtered reception signal to the receiver during reception; and
a switch circuit configured to electrically couple the transmitter and the voltage booster circuit during the transmission, and to electrically couple the receiver and the voltage booster circuit during the reception.

2. The transmit/receive channel of claim 1 further comprising a filtering circuit configured to further filter the filtered reception signal filtered by the voltage booster circuit and output it to the receiver.

3. The transmit/receive channel of claim 2, wherein the voltage booster circuit in combination with the filtering circuit constitutes a bandpass filter.

4. The transmit/receive channel of claim 2, wherein the filtering circuit comprises an inductor and a capacitor.

5. The transmit/receive channel of claim 1, wherein the switch circuit comprises a varistor connected in series with the transmitter and in parallel with the receiver.

6. The transmit/receive channel of claim 1, wherein the switch circuit comprises a switching element connected in parallel with the transmitter and in series with the receiver.

7. The transmit/receive channel of claim 1, wherein the transmitter comprises a switching amplifier and the switching amplifier is also used as a switching element in the switch circuit.

8. A trap circuit connected to an ultrasonic transducer, a transmitter and a receiver, comprising:
a voltage booster circuit configured:
to amplify a voltage of a transmission signal generated by the transmitter and output the amplified transmission signal to the ultrasonic transducer during transmission, and
to filter a reception signal generated by the ultrasonic transducer and output the filtered reception signal to the receiver during reception; and
a switch circuit configured to electrically couple the transmitter and the voltage booster circuit during the transmission, and to electrically couple the receiver and the voltage booster circuit during the reception.

9. An underwater detection device comprising the transmit/receive channel of claim 1.

10. A transmit/receive method of a transmit/receive channel comprising an ultrasonic transducer, a transmitter, a receiver, a voltage booster circuit and a switch circuit, the method comprising:
electrically coupling, by the switch circuit, the transmitter and the voltage booster circuit during transmission;
amplifying, by the voltage booster circuit, a voltage of a transmission signal generated by the transmitter and outputting the amplified transmission signal to the ultrasonic transducer during the transmission;
electrically coupling, by the switch circuit, the receiver and the voltage booster circuit during reception; and
filtering a reception signal generated by the ultrasonic transducer and outputting the filtered reception signal to the receiver during the reception.
